(19) United States
(12) Patent Application Publication
(10) Pub. No.: US 2022/0375722 A1
(43) Pub. Date: Nov. 24, 2022

(54) SELECTIVE GRAPHENE DEPOSITION USING REMOTE PLASMA

(71) Applicant: Lam Research Corporation, Fremont, CA (US)

(72) Inventors: Bhadri N. VARADARAJAN, Beaverton, OR (US); Ieva NARKEVICIUTE, Portland, OR (US)

(21) Appl. No.: 17/753,776

(22) PCT Filed: Sep. 24, 2020
(86) PCT No.: PCT/US2020/052549

§ 371 Date: Mar. 14, 2022

Related U.S. Application Data
(60) Provisional application No. 62/908,271, filed on Sep. 30, 2019.

(51) Int. Cl. H01J 37/32; C23C 16/448; H01L 21/02; H01L 21/285

(52) U.S. Cl. CPC H01J 37/32357; C23C 16/448; H01L 21/0237; H01L 21/28556; C23C 16/45565

(57) ABSTRACT

Graphene is deposited on a metal surface of a substrate using a remote hydrogen plasma chemical vapor deposition technique. The graphene may be deposited at temperatures below 400 C, which is suitable for semiconductor processing applications. Hydrogen radicals are generated in a remote plasma source located upstream of a reaction chamber, and hydrocarbon precursors are flowed into the reaction chamber downstream from the remote plasma source. The hydrocarbon precursors are activated by the hydrogen radicals under conditions to deposit graphene on the metal surface of the substrate in the reaction chamber.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

Graphene is an allotrope of carbon in which the atoms are arrayed in a single atom sheet in a regular hexagonal pattern. Graphene has attracted interest in many fields and industries because of its high electrical conductivity, high thermal conductivity, good mechanical strength and toughness, optical transparency, and high electron mobility, among other favorable properties. Interest is growing in graphene in the semiconductor industry.

The background provided herein is for the purposes of generally presenting the context of the disclosure. Work of the presently named inventors, to the extent that it is described in this background, as well as aspects of the description that may not otherwise qualify as prior art at the time of filing, are neither expressly nor impliedly admitted as prior art against the present disclosure.

### SUMMARY

Provided herein is a method of depositing graphene on a metal surface of a substrate. The method includes providing a substrate in a reaction chamber, where the substrate includes a metal surface. The method further includes flowing one or more hydrocarbon precursors into the reaction chamber and toward the substrate, generating, from a hydrogen source gas, radicals of hydrogen in a remote plasma source that is positioned upstream of the one or more hydrocarbon precursors, and introducing the radicals of hydrogen into the reaction chamber and toward the substrate, where the radicals of hydrogen react with the one or more hydrocarbon precursors to deposit graphene on the metal surface of the substrate.

In some implementations, each of the one or more hydrocarbon precursors includes an alkene or alkyne group. Each of the one or more hydrocarbon precursors may include toluene, benzene, ethylene, propylene, butene, pentene, pentadiene, hexene, acetylene, propyne, butyne, or pentyne. In some implementations, all or substantially all of the radicals of hydrogen in an environment adjacent to the substrate are radicals of hydrogen in a ground state. In some implementations, the substrate is maintained at a temperature equal to or less than about 500° C. during deposition of graphene on the metal surface of the substrate. The substrate may be maintained at a temperature between about 200° C. and about 400° C. during deposition of graphene on the metal surface of the substrate. In some implementations, the method further includes treating the metal surface of the substrate prior to depositing graphene on the metal surface, where treating the metal surface includes exposing the metal surface to a plasma of a reducing gas species. In some implementations, exposing the metal surface to the plasma of the reducing gas species includes exposing the metal surface to a remote hydrogen plasma. In some implementations, treating the metal surface further includes exposing the metal surface to a cyano-based radical species. In some implementations, treating the metal surface further includes generating, from at least a carbon-containing source gas and a nitrogen-containing source gas, a plasma containing the cyano-based radical species, where exposing the metal surface to the cyano-based radical species occurs before or after exposing the metal surface to the plasma of the reducing gas species. In some implementations, exposing the metal surface to the cyano-based radical species occurs simultaneous with exposing the metal surface to the plasma of the reducing gas species, wherein the cyano-based radical species is generated by exposing a downstream carbon-containing precursor having a cyano group to the plasma of the reducing gas species, where the plasma of the reducing gas species is generated in a remote plasma source that is positioned upstream of the downstream carbon-containing precursor. In some implementations, the plasma of the reducing gas species is a plasma of a reducing gas species and of a nitrogen-containing agent, wherein exposing the metal surface to the cyano-based radical species occurs simultaneous with exposing the metal surface to the plasma of the reducing gas species and of the nitrogen-containing agent, wherein the cyano-based radical species is generated by exposing a downstream carbon-containing precursor to the plasma of the reducing gas species, wherein the plasma of the reducing gas species and of the nitrogen-containing agent is generated in a remote plasma source that is positioned upstream of the downstream carbon-containing precursor. In some implementations, the metal surface includes copper, ruthenium, nickel, molybdenum, cobalt, or combinations thereof. In some implementations, a thickness of the graphene on the metal surface is equal to or less than about 5 nm. In some implementations, the substrate is a semiconductor wafer or semiconducting workpiece, wherein the metal surface of the substrate faces towards the remote plasma source. In some implementations, the graphene is deposited under conditions that selectively deposit on a metal of the metal surface of the substrate without depositing on a dielectric material or other non-metal material. In some implementations, the method further includes annealing the graphene on the metal surface of the substrate at a temperature between about 200° C. and about 400° C.

Also provided herein is apparatus for depositing graphene on a metal surface of a substrate. The apparatus includes a reaction chamber, a substrate support in the reaction chamber and configured to support a substrate, where the substrate includes a metal surface, a remote plasma source upstream of the reaction chamber, where the metal surface of the substrate faces towards the remote plasma source, and one or more gas outlets in the reaction chamber and downstream from the remote plasma source. The apparatus further includes a controller configured with instructions for performing the following operations: flow one or more hydrocarbon precursors through the one or more gas outlets into the reaction chamber and toward the substrate, generate, from a hydrogen source gas, radicals of hydrogen in the remote plasma source, and introduce the radicals of hydrogen into the reaction chamber and towards the substrate, wherein the radicals of hydrogen react with the one or more hydrocarbon precursors to deposit graphene on the metal surface of the substrate.

In some implementations, each of the one or more hydrocarbon precursors includes an alkene or alkyne group. In some implementations, all or substantially all of the radicals of hydrogen in an environment adjacent to the substrate are radicals of hydrogen in a ground state. In some implementations, the controller is configured with instructions to perform the following operation: maintain the substrate at a temperature equal to or less than about 500° C. during deposition of graphene on the metal surface of the substrate. In some implementations, the controller is further configured with instructions to perform the following operation: treat the metal surface of the substrate prior to depositing graphene on the metal surface, where treatment is performed by exposing the metal surface to a plasma of a reducing gas species. In some implementations, the controller configured to treat the metal surface of the substrate is further configured to expose the metal surface to a cyano-based radical species. In some implementations, exposing the metal surface to the cyano-based radical species occurs simultaneous with exposing the metal surface to the plasma of the reducing gas species, where the cyano-based radical species is generated by exposing a downstream carbon-containing precursor having a cyano group to the plasma of the reducing gas species, where the plasma of the reducing gas species is generated in a remote plasma source that is positioned upstream of the downstream carbon-containing precursor. In some implementations, the plasma of the reducing gas species is a plasma of a reducing gas species and of a nitrogen-containing agent, where exposing the metal surface to the cyano-based radical species occurs simultaneous with exposing the metal surface to the plasma of the reducing gas species and of the nitrogen-containing agent, where the cyano-based radical species is generated by exposing a downstream carbon-containing precursor to the plasma of the reducing gas species, where the plasma of the reducing gas species and of the nitrogen-containing agent is generated in a remote plasma source that is positioned upstream of the downstream carbon-containing precursor. In some implementations, the metal surface includes copper, ruthenium, nickel, molybdenum, cobalt, or combinations thereof. In some implementations, the substrate is a semiconductor wafer or semiconducting workpiece.

Also provided herein is a semiconducting device. The semiconducting device includes a semiconductor substrate having a temperature sensitive underlayer, where the temperature sensitive underlayer has a temperature sensitive limit, and a graphene film deposited on the temperature sensitive underlayer.

In some implementations, the temperature sensitive underlayer includes a transition metal. In some implementations, the temperature sensitive limit is between about 400° C. and about 700° C.

Also provided herein is a method of depositing graphene on a metal surface of a substrate. The method includes providing a substrate in a reaction chamber, where the substrate includes a metal surface, and depositing graphene on the metal surface of the substrate, where the substrate is maintained at a temperature between about 200° C. and about 400° C. during deposition.

In some implementations, depositing the graphene on the metal surface includes exposing the metal surface to a remote hydrogen plasma, wherein one or more hydrocarbon precursors are provided in an environment adjacent to the metal surface of the substrate. In some implementations, the graphene selectively deposits on a metal of the metal surface of the substrate without depositing on a dielectric material or other non-metal material of the substrate.

Also provided herein is method of depositing graphene on a metal surface of a substrate. The method includes providing a substrate in a reaction chamber, where the substrate includes a metal surface, treating the metal surface of the substrate prior to depositing graphene on the metal surface, where treating the metal surface includes exposing the metal surface to a plasma of a reducing gas species simultaneous with exposing the metal surface to a cyano-based radical species, and depositing graphene on the metal surface of the substrate.

In some implementations, the substrate is maintained at a temperature between about 200° C. and about 400° C. during deposition. In some implementations, the plasma of the reducing gas species is a plasma of a reducing gas species and of a nitrogen-containing agent, where the cyano-based radical species is generated by exposing a downstream carbon-containing precursor to the plasma of the reducing gas species and of the nitrogen-containing agent, where the plasma of the reducing gas species and of the nitrogen-containing agent is generated in a remote plasma source that is positioned upstream of the downstream carbon-containing precursor.

### BRIEF DESCRIPTION OF THE DRAWINGS

FIG. 1A illustrates a cross-sectional schematic of an example substrate having a metal surface with graphene deposited thereon according to some implementations.

FIG. 1B illustrates a cross-sectional schematic of an example graphene barrier layer in a dual damascene structure according to some implementations.

FIG. 2 illustrates a schematic diagram of an example plasma processing apparatus with a remote plasma source according to some implementations.

FIG. 3 illustrates a graph showing Raman spectra of examples of single layer graphene and multi-layer graphene according to some implementations.

FIG. 4 illustrates a flow diagram of an example method of depositing graphene on a metal surface of a substrate according to some implementations.

### DETAILED DESCRIPTION

In the present disclosure, the terms “semiconductor wafer,” “wafer,” “substrate,” “wafer substrate,” and “partially fabricated integrated circuit” are used interchangeably. One of ordinary skill in the art would understand that the term “partially fabricated integrated circuit” can refer to a silicon wafer during any of many stages of integrated circuit fabrication. A wafer or substrate used in the semiconductor device industry typically has a diameter of 200 mm, or 300 mm, or 450 mm. The following detailed description assumes the present disclosure is implemented on a wafer. However, the present disclosure is not so limited. The work piece may be of various shapes, sizes, and materials. In addition to semiconductor wafers, other work pieces that may take advantage of the present disclosure include various articles such as printed circuit boards and the like.

There is a growing interest in synthesizing large-area graphene films in semiconductor applications. However, there are many challenges associated with production of graphene in sufficient quantities and under suitable conditions for semiconductor integration. Many production methods suffer from low surface coverage because of the difficulty of growing graphene with minimal defects. Thus, scalability to produce large-area graphene films represents a particular problem, especially large-area graphene films on semiconductor wafers. Furthermore, graphene films are typically grown by thermal chemical vapor deposition (CVD). Thermal CVD methods are generally favored for synthesis of large-area, high-quality graphene. However, thermal CVD of graphene is often performed at temperatures greater than 700° C., such as between about 800° C. and about 1000° C., which is not compatible with semiconductor applications. Under such high temperatures, various materials such as semiconductors and metals on semiconductor wafers may be physically damaged.

Thermal CVD is a common method of depositing graphene. The thermal CVD process involves at least two steps: activation of gaseous precursors and chemical reaction to form a stable, solid film on a suitable substrate. In thermal CVD, activation of gaseous precursors can occur by thermal decomposition. At elevated temperatures, hydrocarbon precursors thermally decompose and adsorb onto a substrate surface. Hydrocarbon radicals are chemically reactive and may interact with the substrate surface. The substrate surface may be a metal surface that acts as a catalyst for nucleation and growth of graphene. Without being limited by any theory, the catalytic metal surface may dehydrogenate the hydrocarbon radicals so that carbon atoms may bond with other carbon atoms, thereby promoting nucleation and growth of graphene. Various transition metals such as copper have been recognized as catalysts for nucleation and growth of graphene.

Activation of hydrocarbon species and graphene growth can depend on factors such as temperature and the metal surface on which graphene is grown. In addition, graphene growth can depend on carbon solubility on the metal surface. If the metal has high carbon solubility, carbon more easily dissolves in the metal and tends to precipitate on the metal surface. This generally leads to less uniform graphene layers and more microstructural defects owing to multiple nucleation sites and an unpredictable quantity of segregated carbon on the metal surface. Nickel substrates, for example, have high carbon solubility and typically lead to multiple layers of low-quality graphene or disordered carbon. If the metal has low carbon solubility, carbon less easily dissolves in the metal and results in an extensive surface migration of carbon adatoms on the metal surface and minimal diffusion into bulk metal. This generally leads to more uniform graphene layers and fewer microstructural defects owing to more controlled growth. Copper substrates, for example, have low carbon solubility and result in epitaxial growth of high-quality graphene. The high-quality graphene may be grown as a single layer, bilayer, or few-layer graphene film.

Plasma-enhanced chemical vapor deposition (PECVD) is another method of depositing graphene. Whereas thermal CVD methods activate hydrocarbon precursors by thermal decomposition, energized electrons generated by plasma cause ionization, excitation, and dissociation of hydrocarbon precursors in PECVD methods. The plasma may be formed in-situ or remotely. Typically, hydrocarbon precursors (e.g., methane) are activated in a plasma and a substrate is exposed to the plasma. The plasma may be generated using a radio-frequency (RF) plasma source, microwave (MW) plasma source, surface wave (SW) plasma source, or remote plasma source. By way of an example, molecular hydrogen and methane gas may be introduced in a reaction chamber and direct RF plasma may be ignited to promote graphene growth on a substrate. With PECVD, graphene growth in some PECVD methods may be performed at lower temperatures compared to thermal CVD methods, where the temperatures may be between about 400° C. and about 600° C. Moreover, graphene growth in some PECVD methods may be accomplished on non-metal substrates such as dielectric materials. In other words, plasma-based methods may deposit graphene in the absence of metal catalysts. Though plasma-based methods may deposit graphene at lower temperatures and without the assistance of metal catalysts, many plasma-based methods face challenges depositing large-area, high-quality graphene.

Graphene Deposition Using Remote Hydrogen Plasma

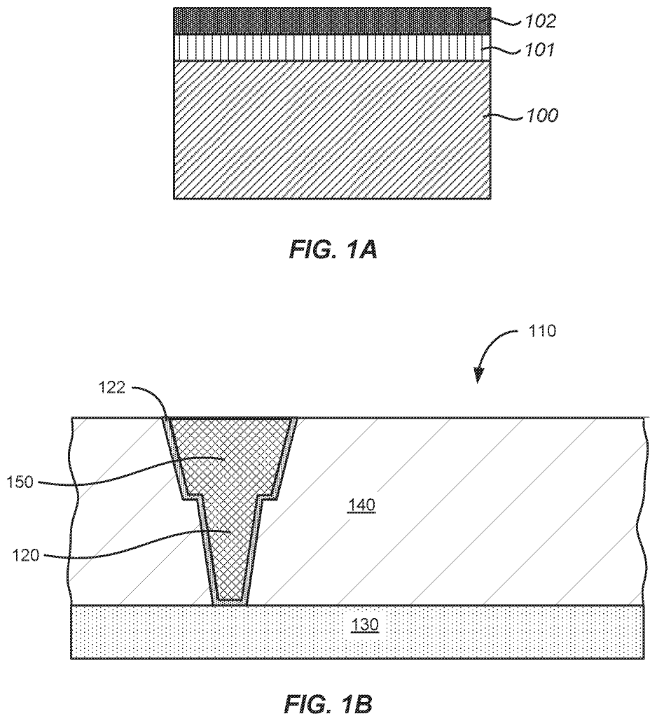

FIG. 1A illustrates a cross-sectional schematic of an example substrate having a metal surface with graphene deposited thereon according to some implementations. The substrate 100 can be any wafer, semiconductor wafer, partially fabricated integrated circuit, printed circuit board, display screen, or other appropriate workpiece. In some implementations, the substrate 100 is a semiconductor substrate such as a silicon (Si) substrate. The substrate 100 can include a metal surface 101. As discussed below, the metal surface 101 can also be referred to as a temperature sensitive underlayer. In some implementations, the metal surface 101 can include any appropriate metal such as a transition metal. For example, the metal surface 101 can include copper (Cu), ruthenium (Ru), nickel (Ni), molybdenum (Mo), cobalt (Co), or combinations thereof. A graphene film 102 can be deposited on the metal surface 101.

In the present disclosure, depositing the graphene film 102 on the metal surface 101 of the substrate 100 may be accomplished by remote hydrogen plasma CVD. The remote hydrogen plasma CVD method may deposit the graphene film 102 at low temperatures that are compatible with semiconductor processing, such as back end of line (BEOL) semiconductor processing. In some implementations, the graphene film 102 may be deposited at temperatures below about 500° C., below about 450° C., below about 400° C., below about 350° C., below about 300° C., or between about 200° C. and about 400° C. As described below, a hydrocarbon precursor is flowed to the metal surface 101 of the substrate 100 and hydrogen radicals are generated in a remote plasma source upstream of the hydrocarbon precursor flow. The hydrogen radicals interact with the hydrocarbon precursor to activate the hydrocarbon precursor downstream from the remote plasma source, and the activated hydrocarbon precursor interacts with the metal surface 101 to cause graphene film 102 to deposit. In some implementations, the hydrocarbon precursor includes an alkene group or alkyne group.

In some implementations of the present disclosure, the substrate 100 can include a temperature sensitive underlayer 101. The temperature sensitive underlayer 101 may have a temperature sensitive limit. Above the temperature sensitive limit of the temperature sensitive underlayer 101, the temperature sensitive underlayer 101 melts or is otherwise physically damaged. The temperature sensitive limit may be between about 400° C. and about 700° C. for many materials of the temperature sensitive underlayer 101. Thermal CVD methods and many conventional plasma-based CVD methods exceed the temperature sensitive limit of the temperature sensitive underlayer 101. Examples of temperature sensitive underlayers 101 can include transition metals such as copper, cobalt, and ruthenium. In the present disclosure, a graphene film 102 is deposited on the temperature sensitive underlayer 101. In some implementations, the graphene film 102 is deposited at sufficiently low temperatures that do not melt or otherwise physically damage the temperature sensitive underlayer 101. The substrate 100 may be a semiconductor wafer or semiconductor workpiece. Hence, the graphene film 102 may be deposited as a large-area graphene film on the substrate 100 at full wafer level.

Many conventional plasma-based CVD methods used in synthesizing graphene activate hydrocarbons that are alkanes (e.g., methane). When using various conventional plasma-based CVD methods, graphene deposition is not necessarily selective and may deposit on metals, dielectrics, and other materials. Furthermore, many conventional plasma-based CVD methods generate carbon radicals by igniting plasma with the hydrocarbon precursor. Regardless of whether the plasma is generated in-situ or remotely, the substrate is subsequently exposed to the plasma containing carbon radicals. The term “remote” in literature generally refers to the remoteness of the substrate from the plasma. The precursor gas itself is typically introduced in the plasma-generating region. In some instances, a remote plasma-based CVD approach deposits graphene on a backside of a metal foil (e.g., copper foil), since the front side of the metal foil faces the remote plasma source and is exposed to more energized ions/radicals during plasma exposure. Direct plasma exposure on the front side adversely affects film quality and generally results in more disordered carbon growth. Accordingly, many conventional plasma-based CVD methods are not able to grow high-quality graphene for full wafer deposition.

In contrast to conventional plasma-based CVD methods, the remote hydrogen plasma CVD method of the present disclosure synthesizes high-quality graphene at full wafer level. As used herein, a “remote plasma” is a plasma in which plasma generation occurs at a location that is remote from the substrate. Here, the remote hydrogen plasma in the present disclosure contains hydrogen radicals but does not contain carbon radicals. Instead, carbon radicals are generated downstream from a remote plasma source. This means that in the “remote plasma” of the present disclosure, precursor gas is not introduced into the plasma-generating region. Hydrocarbon precursors are independently flowed into a reaction chamber and are activated by hydrogen radicals generated from the remote plasma source. Moreover, the carbon radicals are generated from hydrocarbon precursors containing alkene or alkyne groups. In fact, hydrocarbon precursors that are alkanes (e.g., methane) do not deposit in the present disclosure. When using the remote hydrogen plasma CVD method of the present disclosure, graphene deposition selectively deposits on metal surfaces. Graphene does not deposit on dielectric or other non-metal surfaces in the present disclosure.

In contrast to conventional thermal CVD methods, the remote hydrogen plasma CVD method of the present disclosure can deposit a high-quality graphene film at low temperatures suitable for semiconductor applications. For example, a high-quality graphene film can serve as an effective barrier layer in damascene or dual damascene structures. Further, the high-quality graphene can serve as a cap layer on top of the metal surface, which reduces resistance by reducing surface scattering. However, it will be understood that the high-quality graphene film may be used in a wide number of industrial applications.

FIG. 1B illustrates a cross-sectional schematic of an example graphene barrier layer in a dual damascene structure according to some implementations. A substrate 110 may include a dielectric layer 140 through which a trench and via 120 is formed. The via 120 may provide electrical interconnection between a lower metal line 130 and an upper metal line 150. The substrate 110 may be a semiconductor substrate. The via 120 may be formed by etching a recess through the dielectric layer 140 and filling the recess with a metal such as copper. A graphene barrier layer 122 may be formed, placed, or positioned between the via 120 and the dielectric layer 140. The graphene barrier layer 122 may serve as an effective diffusion barrier layer to protect the dielectric layer 140 and underlying active devices from diffusion of metal. Thus, the graphene barrier layer 122 may limit electromigration metal atoms due to current and diffusion of metal atoms into the dielectric layer 140 and underlying active devices. The electrically conductive properties of the graphene barrier layer 122 may also lower the effective resistivity of metal lines connected to the via 120, including the lower metal line 130 and the upper metal line 150 due to reduced scattering. The graphene barrier layer 122 may be deposited using the remote hydrogen plasma CVD method described herein.

While the above description relates to using graphene as a diffusion barrier layer, graphene may alternatively be used as a cap layer. In such instances, a graphene film may be deposited on top of the upper metal line 150. Using the methods described in the present disclosure, graphene may be selectively deposited on top of a metal surface, where in some implementations the graphene is a cap layer on top of the upper metal line 150.

One aspect of the disclosure is an apparatus configured to accomplish the graphene deposition methods described herein. A suitable apparatus includes hardware for accomplishing the process operations and a system controller having instructions for controlling process operations in accordance with the present disclosure. In some implementations, the apparatus for performing the aforementioned process operations can include a remote plasma source. A remote plasma source provides mild reaction conditions compared to a direct plasma. An example of a suitable remote plasma apparatus is described in U.S. patent application Ser. No. 14/062,648, filed Oct. 24, 2013, which is incorporated herein by reference in its entirety and for all purposes.

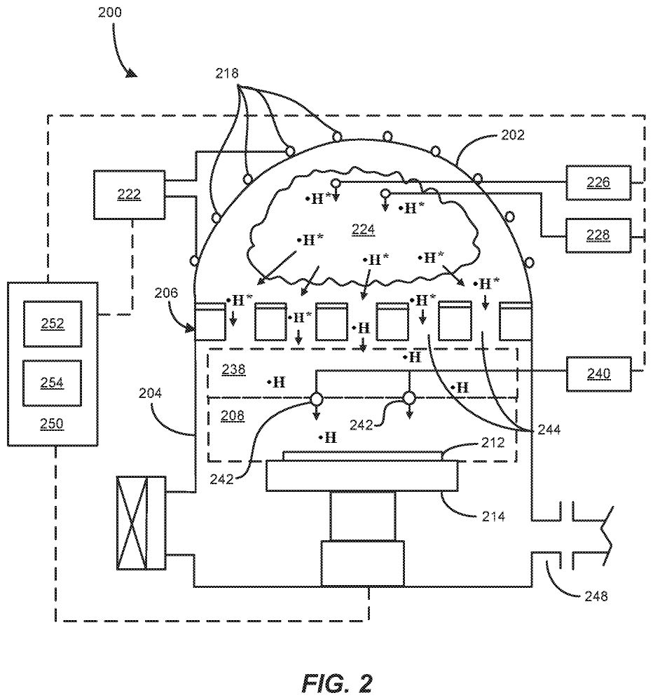

FIG. 2 illustrates a schematic diagram of an example plasma processing apparatus with a remote plasma source according to some implementations. The plasma processing apparatus 200 includes the remote plasma source 202 separated from a reaction chamber 204. The remote plasma source 202 is fluidly coupled with the reaction chamber 204 via a showerhead 206, which may also be referred to as a multiport gas distributor. Radical species are generated in the remote plasma source 202 and supplied to the reaction chamber 204. One or more hydrocarbon precursors are supplied to the reaction chamber 204 downstream from the remote plasma source 202 and downstream from the showerhead 206. The one or more hydrocarbon precursors react with the radical species in a chemical vapor deposition zone 208 of the reaction chamber 204 to deposit a graphene film on a front surface of a substrate 212. The chemical vapor deposition zone 208 includes an environment adjacent to the front surface of the substrate 212, where the front surface of the substrate 212 faces the remote plasma source 202.

The substrate 212 is supported on a substrate support or pedestal 214. The pedestal 214 may move within the reaction chamber 204 to position the substrate 212 within the chemical vapor deposition zone 208. In the embodiment shown in FIG. 2, pedestal 214 is shown having elevated the substrate 210 within the chemical vapor deposition zone 208. The pedestal 214 may also adjust the temperature of the substrate 212 in some embodiments, which can provide some selective control over thermally activated surface reactions on the substrate 212.

FIG. 2 shows a coil 218 arranged around the remote plasma source 202, where the remote plasma source 202 includes an outer wall (e.g., quartz dome). The coil 218 is electrically coupled to a plasma generator controller 222, which may be used to form and sustain plasma within a plasma region 224 via inductively coupled plasma generation. In some implementations, the plasma generator controller 222 may include a power supply for supplying power to the coil 218, where the power can be in a range between about 1 and 6 kilowatts (kW) during plasma generation. In some implementations, electrodes or antenna for parallel plate or capacitively coupled plasma generation may be used to generate a continuous supply of radicals via plasma excitation rather than inductively coupled plasma generation. Regardless of the mechanism used to ignite and sustain the plasma in the plasma region 224, radical species may continuously be generated using plasma excitation during film deposition. In some implementations, hydrogen radicals are generated under approximately steady-state conditions during steady-state film deposition, though transients may occur at the beginning and end of film deposition.

A supply of hydrogen radicals may be continuously generated within the plasma region 224 while hydrogen gas or other source gas is being supplied to the remote plasma source 202. Excited hydrogen radicals may be generated in the remote plasma source 202. If not re-excited or re-supplied with energy, or re-combined with other radicals, the excited hydrogen radicals lose their energy, or relax. Thus, excited hydrogen radicals may relax to form hydrogen radicals in a substantially low energy state or ground state. The hydrogen radicals in the substantially low energy state or ground state.

The hydrogen gas (H₂) or other source gas may be diluted with one or more additional gases. These one or more additional gases may be supplied to the remote plasma source 202. In some implementations, the hydrogen gas or other source gas is mixed with one or more additional gases to form a gas mixture, where the one or more additional gases can include a carrier gas. Non-limiting examples of additional gases can include helium (He), neon (Ne), argon (Ar), krypton (Kr), xenon (Xe), and nitrogen (N₂). The one or more additional gases may support or stabilize steady-state plasma conditions within the remote plasma source 202 or aid in transient plasma ignition or extinction processes. In some implementations, diluting hydrogen gas or other source gas with helium, for example, may permit higher total pressures without concomitant plasma breakdown. Put another way, a dilute gas mixture of hydrogen gas and helium may permit higher total gas pressure without increasing plasma power to the remote plasma source 202. In certain embodiments, hydrogen gas is provided in a carrier such helium. As an example, hydrogen gas may be provided in a helium carrier at a concentration of about 1-25% hydrogen or about 1-10% hydrogen.

As shown in FIG. 2, a source gas supply 226 is fluidly coupled with the remote plasma source 202 for supplying the hydrogen gas or source gas. In addition, an additional gas supply 228 is fluidly coupled with the remote plasma source 202 for supplying the one or more additional gases. The one or more additional gases may also include a co-reactant gas. While the embodiment in FIG. 2 depicts the gas mixture of the source gas and the one or more additional gases being introduced through separate gas outlets, it will be understood that the gas mixture may be introduced directly into the remote plasma source 202. That is, a pre-mixed dilute gas mixture may be supplied to the remote plasma source 202 through a single gas outlet.

Gases, such as excited hydrogen and helium radicals and relaxed gases/radicals, flow out of the remote plasma source 202 and into the reaction chamber 204 via the showerhead 206. Gases within the showerhead 206 and within the reaction chamber 204 are generally not subject to continued plasma excitation therein. In some implementations, the showerhead 206 includes an ion filter and/or a photon filter. Filtering ions and/or photons may reduce substrate damage, undesirable re-excitation of molecules, and/or selective breakdown or decomposition of hydrocarbon precursors within the reaction chamber 204. Showerhead 206 may have a plurality of gas ports 234 to diffuse the flow of gases into the reaction chamber 204. In some implementations, the plurality of gas ports 234 may be mutually spaced apart. In some implementations, the plurality of gas ports 234 may be arranged as an array of regularly spaced apart channels or through-holes extending through a plate separating the remote plasma source 202 and the reaction chamber 204. The plurality of gas ports 234 may smoothly disperse and diffuse exiting radicals from the remote plasma source 202 into the reaction chamber 204.

Typical remote plasma sources are far removed from reaction vessels. Consequently, radical extinction and recombination, e.g., via wall collision events, may reduce active species substantially. In contrast, in some implementations, dimensions for the plurality of gas ports 234 may be configured in view of the mean free path or gas flow residence time under typical processing conditions to aid the free passage of radicals into the reaction chamber 204. In some implementations, openings for the plurality of gas ports 234 may occupy between about 5% and about 20% of an exposed surface area of the showerhead 206. In some implementations, the plurality of gas ports 234 may each have an axial length to diameter ratio of between about 3:1 and 10:1 or between about 6:1 and about 8:1. Such aspect ratios may reduce wall-collision frequency for radical species passing through the plurality of gas ports 234 while providing sufficient time for a majority of excited state radical species to relax to ground state radical species. In some implementations, dimensions of the plurality of gas ports 234 may be configured so that the residence time of gases passing through the showerhead 206 is greater than the typical energetic relaxation time of an excited state radical species. Excited state radical species for hydrogen source gas may be denoted by .H* in FIG. 2 and ground state radical species for hydrogen source gas may be denoted by .H in FIG. 2.

In some implementations, excited state radical species exiting the plurality of gas ports 234 may flow into a relaxation zone 238 contained within an interior of the reaction chamber 204. The relaxation zone 238 is positioned upstream of the chemical vapor deposition zone 208 but downstream of the showerhead 206. Substantially all or at least 90% of the excited state radical species exiting the showerhead 206 will transition into relaxed state radical species in the relaxation zone 238. Put another way, almost all of the excited state radical species (e.g., excited hydrogen radicals) entering the relaxation zone 238 become de-excited or transition into a relaxed state radical species (e.g., ground state hydrogen radicals) before exiting the relaxation zone 238. In some implementations, process conditions or a geometry of the relaxation zone 238 may be configured so that the residence time of radical species flowing through the relaxation zone 238, e.g., a time determined by mean free path and mean molecular velocity, results in relaxed state radical species flowing out of the relaxation zone 238.

With the delivery of radical species to the relaxation zone 238 from the showerhead 206, one or more hydrocarbon precursors may be introduced into the chemical vapor deposition zone 208. The one or more hydrocarbon precursors may be introduced via a gas distributor or gas outlet 242, where the gas outlet 242 may be fluidly coupled with a precursor supply source 240. The relaxation zone 238 may be contained within a space between the showerhead 206 and the gas outlet 242. The gas outlet 242 may include mutually spaced apart openings so that the flow of the one or more hydrocarbon precursors may be introduced in a direction parallel with gas mixture flowing from the relaxation zone 238. The gas outlet 242 may be located downstream from the showerhead 206 and the relaxation zone 238. The gas outlet 242 may be located upstream from the chemical vapor deposition zone 208 and the substrate 212. The chemical vapor deposition zone 208 is located within the interior of the reaction chamber 204 and between the gas outlet 242 and the substrate 212.

Substantially all of the flow of the one or more hydrocarbon precursors may be prevented from mixing with excited state radical species adjacent to the showerhead 206. Relaxed or ground state radical species mix in a region adjacent to the substrate 212 with the one or more hydrocarbon precursors. The chemical vapor deposition zone 208 includes the region adjacent to the substrate 212 where the relaxed or ground state radical species mix with the one or more hydrocarbon precursors. The relaxed or ground state radical species mix with the one or more hydrocarbon precursors in the gas phase during CVD formation of graphene.

In some implementations, a co-reactant may be introduced from the showerhead 206 and flowed along with the radical species generated in the remote plasma source 202 and into the reaction chamber 204. This may include radicals and/or ions of a co-reactant gas provided in the remote plasma source 202. The co-reactant may be supplied from the additional gas supply 228. In some implementations, the co-reactant may include a nitrogen-containing agent such as nitrogen gas (N₂). For example, radicals and/or ions of nitrogen may be generated and flowed with the radical species of hydrogen during pretreatment of a metal surface of the substrate 212.

The gas outlet 242 may be separated from the showerhead 206 by a sufficient distance to prevent back diffusion or back streaming of the one or more hydrocarbon precursors. This can afford sufficient time for radical species of hydrogen to transition from an excited state to a relaxed state (e.g., ground state). In some implementations, the gas outlet 242 may be separated from the plurality of gas ports 234 by a distance between about 0.5 inches and about 5 inches, or between about 1.5 inches and about 4.5 inches, or between about 1.5 inches and about 3 inches.

Process gases may be removed from the reaction chamber 204 via an outlet 248 that is fluidly coupled to a pump (not shown). Thus, excess hydrocarbon precursors, co-reactants, radical species, and diluent and displacement or purge gases may be removed from the reaction chamber 204. In some implementations, a system controller 250 is in operative communication with the plasma processing apparatus 200. In some implementations, the system controller 250 includes a processor system 252 (e.g., microprocessor) configured to execute instructions held in a data system 254 (e.g., memory). In some implementations, the system controller 250 may be in communication with the plasma generator controller 222 to control plasma parameters and/or conditions. In some implementations, the system controller 250 may be in communication with the pedestal 214 to control pedestal elevation and temperature. In some implementations, the system controller 250 may control other processing conditions, such as RF power settings, frequency settings, duty cycles, pulse times, pressure within the reaction chamber 204, pressure within the remote plasma source 202, gas flow rates from the source gas supply 226 and the additional gas supply 228, gas flow rates from the precursor supply source 240 and other sources, temperature of the pedestal 214, and temperature of the reaction chamber 204, among others.

The controller 250 may contain instructions for controlling process conditions for the operation of the plasma processing apparatus 200. The controller 250 will typically include one or more memory devices and one or more processors. The processor may include a CPU or computer, analog and/or digital input/output connections, stepper motor controller boards, etc. Instructions for implementing appropriate control operations are executed on the processor. These instructions may be stored on the memory devices associated with the controller 250 or they may be provided over a network.

In certain embodiments, the controller 250 controls all or most activities of the plasma processing apparatus 200 described herein. For example, the controller 250 may control all or most activities of the plasma processing apparatus 200 associated with depositing graphene and, optionally, other operations in a fabrication flow that includes the graphene. The controller 250 may execute system control software including sets of instructions for controlling the timing, gas composition, gas flow rates, chamber pressure, chamber temperature, RF power levels, substrate position, and/or other parameters. Other computer programs, scripts, or routines stored on memory devices associated with the controller 250 may be employed in some embodiments. To provide relatively mild reactive conditions at the environment adjacent to the substrate 212, parameters such as the RF power levels, gas flow rates to the plasma region 224, gas flow rates to the chemical vapor deposition zone 208, and timing of the plasma ignition can be adjusted and maintained by controller 250. Additionally, adjusting the substrate position may further reduce the presence of high-energy radical species at the environment adjacent to the substrate 212. In a multi-station reactor, the controller 250 may comprise different or identical instructions for different apparatus stations, thus allowing the apparatus stations to operate either independently or synchronously.

In some embodiments, the controller 250 may include instructions for performing operations such as flowing one or more hydrocarbon precursors through the gas outlet 242 into the reaction chamber 204, providing a source gas into the remote plasma source 202, generating one or more radical species of the source gas in the remote plasma source 202 upstream of the one or more hydrocarbon precursors, introducing the one or more radical species from the remote plasma source 202 into the reaction chamber 204 to react with the one or more hydrocarbon precursors to deposit a graphene on a metal surface of the substrate 212. The one or more radical species in the reaction chamber 204 in an environment adjacent to the substrate 212 may be hydrogen radicals in a ground state. In some implementations, the controller 250 may include instructions for treating the metal surface of the substrate 212 prior to depositing graphene. In some implementations, the controller 250 may include instructions for maintaining a temperature of the substrate 212 equal to or less than about 400° C., or between about 200° C. and about 400° C. In some implementations, each of the one or more hydrocarbon precursors includes an alkene or alkyne group.

In some embodiments, the apparatus 200 may include a user interface associated with controller 250. The user interface may include a display screen, graphical software displays of the apparatus 200 and/or process conditions, and user input devices such as pointing devices, keyboards, touch screens, microphones, etc.

The computer program code for controlling the above operations can be written in any conventional computer readable programming language: for example, assembly language, C, C++, Pascal, Fortran, or others. Compiled object code or script is executed by the processor to perform the tasks identified in the program.

Signals for monitoring the process may be provided by analog and/or digital input connections of the system controller. The signals for controlling the process are output on the analog and digital output connections of the processing system.

In general, the methods described herein can be performed on systems including semiconductor processing equipment such as a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. In general, the electronics are referred to as the controller, which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, RF generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials (e.g., silicon carbide), surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

In addition to graphene deposition described herein, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

Raman spectroscopy can be used for the characterization of graphene. Raman spectroscopy can also be suitable for determining the number of graphene layers as well as the amount of disorder in graphene. By identifying certain features of graphene in a Raman spectrum, graphene can be distinguished from disordered or amorphous carbon layers.

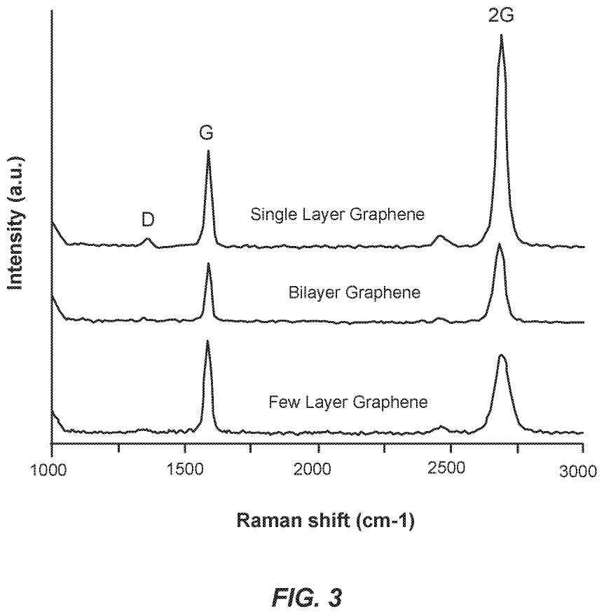

FIG. 3 illustrates a graph showing Raman spectra of examples of single layer graphene and multi-layer graphene according to some implementations. Graphene can be characterized in a Raman spectrum by the presence of a G peak at around 1580 cm⁻¹ and a 2D peak at around 2680 cm⁻¹, where the 2D peak is equal to or greater in intensity than the G peak. If the 2D peak is significantly less in intensity than the G peak, then the deposited film is not characterized as graphene. Disordered carbon or amorphous carbon, however, can be characterized in a Raman spectrum by the presence of a D peak at around 1380 cm¹. As disorder increases, the Raman intensity of the D peak usually increases.

Raman spectroscopy can also be used to determine the number of graphene layers. In some implementations, the ratio of the intensity of the 2D peak to the intensity of the G peak (I_{2D}/I_{G}) can correspond to the number of graphene layers. Specifically, if the ratio of I_{2D}/I_{G} is greater than 2, then a deposited graphene film corresponds to single layer graphene. If the ratio of I_{2D}/I_{G} is slightly greater than 1 or slightly less than 1 as shown in FIG. 3, then a deposited graphene film may correspond to bilayer graphene or few layer graphene, respectively.

In the present disclosure, the graphene film deposited by remote hydrogen plasma CVD on a metal surface has a thickness equal to or less than about 10 nm, equal to or less than about 5 nm, equal to or less than about 3 nm, or equal to or less than about 1 nm. The thickness of the graphene film can depend on the metal surface on which it is deposited. For example, the graphene film may be a monolayer or a few monolayers thick when deposited on copper, and so the thickness may be less than about 1 nm. The graphene film may be a single layer graphene, bilayer graphene, or few layer graphene. This can occur where the graphene film is deposited on a metal such as copper. In another example, the graphene film may be a few nanometers thick (e.g., about 2-3 nm) when deposited on other metals such as cobalt.

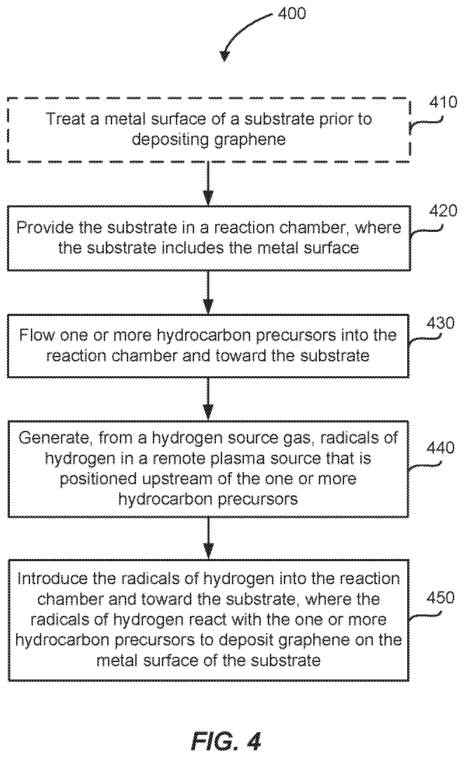

FIG. 4 illustrates a flow diagram of an example method of depositing graphene on a metal surface of a substrate according to some implementations. The operations of a process 400 may be performed in different orders and/or with different, fewer, or additional operations. The operations of the process 400 may be performed using a plasma processing apparatus shown in FIG. 2. In some implementations, the operations of the process 400 may be implemented, at least in part, according to software stored in one or more non-transitory computer readable media.

At block 410 of the process 400, a metal surface of a substrate may be optionally treated prior to depositing graphene. Graphene deposition can depend on the smoothness and purity of the metal surface on which graphene is grown. Surface preparation techniques may be applied on the metal surface to polish the substrate and remove impurities. Polishing the substrate may be performed by a light etch in some implementations. Removal of impurities may be performed by a chemical treatment that removes, for example, metal oxides. Removal of impurities may additionally or alternatively involve removal of residues or contaminants from chemical mechanical planarization (CMP) processes. In some implementations, the treatment of the metal surface may occur before any diffusion barrier deposition or etch stop deposition.

In some implementations, treating the metal surface of the substrate can include exposing the metal surface to a plasma of a reducing gas species. Treatment of the metal surface can at least include removal of impurities and/or reduction of metal oxides by exposure to plasma. In some implementations, the plasma can include ions and radicals of a reducing gas species. Reducing gas species can include, for example, hydrogen gas (H₂), ammonia (NH₃), or combinations thereof. Thus, the metal surface may be treated by an H₂ plasma, NH₃ plasma, or H₂/NH₃ plasma. The plasma may be a direct (in-situ) plasma or remote plasma. In some implementations, exposing the metal surface to the plasma of the reducing gas species includes exposing the metal surface to a remote hydrogen plasma.

In some implementations, treating the metal surface further includes exposing the metal surface to a cyano-based radical species. In some other implementations, treating the metal surface includes exposing the metal surface to a cyano-based radical species as an alternative to exposing the metal surface to the reducing gas species. Cyano-based radical species may perform a light etch for smoothing the metal surface prior to graphene growth. Exposing the metal surface to the cyano-based radical species can occur before or after exposing the metal surface to the plasma of the reducing gas species. This can be referred to as a multi-step pretreatment process. The multi-step pretreatment process, or at least some steps of the multi-step pretreatment process, may be performed in the same or different apparatus than the plasma processing apparatus for depositing graphene. Exposing the metal surface to the cyano-based radical species can occur simultaneous with exposing the metal surface to the plasma of the reducing gas species. This can be referred to as a single-step pretreatment process. The single-step pretreatment process may be performed in the same or different apparatus than the plasma processing apparatus for depositing graphene.

In a multi-step pretreatment process, the cyano-based radical species may be generated by igniting a plasma, where the plasma may be a direct (in-situ) plasma or a remote plasma. The cyano-based radical species may be generated from a gas mixture containing at least a carbon-containing source gas and a nitrogen-containing source gas or from a gas mixture containing a precursor having a carbon-nitrogen (CN) bond. Thus, treating the metal surface can further include generating, from at least a carbon-containing source gas and a nitrogen-containing source gas or from a precursor having a carbon-nitrogen bond, plasma containing the cyano-based radical species. For example, a gas mixture of a hydrocarbon precursor, nitrogen gas, and hydrogen gas may be supplied to a plasma generator, and plasma of the gas mixture may be ignited to form the cyano-based radical species.

In a single step pretreatment process, the cyano-based radical species may be generated by activating a downstream carbon-containing precursor. Activation of the downstream carbon-containing precursor is simultaneous with surface pretreatment by the plasma of the reducing gas species. In such instances, a remote plasma source is positioned upstream of the downstream carbon-containing precursor, where the plasma of the reducing gas species is generated in the remote plasma source. In some implementations, the downstream carbon-containing precursor may be a hydrocarbon precursor. Thus, the downstream carbon-containing precursor may be chemically the same or different than the hydrocarbon precursor used in depositing graphene. In such cases, the plasma of the reducing gas species is a plasma of a reducing gas species and of a nitrogen-containing agent. For example, the reducing gas species can include hydrogen gas. The nitrogen-containing agent can include nitrogen gas. Hence, the plasma of the reducing gas species and of the nitrogen-containing agent can be a remote H₂ and N₂ plasma. The concentration of the reducing gas species may be greater than the concentration of the nitrogen-containing agent in the plasma. Without being limited by any theory, it is believed that ions/radicals of the nitrogen-containing agent interact with the downstream carbon-containing precursor to form the cyano-based radical species. The cyano-based radical species can perform a light etch for smoothing the metal surface and the plasma of the reducing gas species can reduce metal oxides to metal on the metal surface. In some other implementations, the downstream carbon-containing precursor may be precursor gas containing one or more CN bonds. Such a precursor may be activated by the plasma of the reducing gas species, where the plasma of the reducing gas species is a remote plasma generated upstream in the remote plasma source. In some instances, the plasma of the reducing gas species is a remote hydrogen plasma. Without being limited by any theory, it is believed that ions/radicals of hydrogen interact with the downstream carbon-containing precursor having one or more CN bonds to form the cyano-based radical species.

Though the treatment operation at block 410 may be described in terms of a multi-step pretreatment process and a single step pretreatment process, it will be understood that pretreatment of the metal surface is not limited to such techniques. The metal surface of the substrate may be pretreated prior to graphene deposition using any suitable surface preparation technique known in the art.

At block 420 of the process 400, the substrate is provided in a reaction chamber, where the substrate includes the metal surface. In some implementations, the substrate may already be provided in the reaction chamber during treatment at block 410. The substrate may be a semiconductor substrate used in semiconductor applications. The metal surface can include any appropriate metal such as a transition metal. For example, the metal surface can include copper, ruthenium, nickel, molybdenum, cobalt, or combinations thereof. The metal surface can serve as a catalyst for promoting graphene nucleation and growth. Deposition of graphene in the present disclosure may be selective to the particular metal of the metal surface. Put another way, deposition of graphene in the present disclosure may not occur on dielectric surfaces or other non-metal surfaces.

The reaction chamber may include a substrate support or pedestal for supporting the substrate. A remote plasma source may be fluidly coupled to the reaction chamber via a showerhead. The metal surface of the substrate may be facing towards the remote plasma source. A precursor gas line may be separately fluidly coupled to the reaction chamber via one or more gas outlets. The one or more gas outlets may be located downstream from the remote plasma source. The one or more gas outlets may deliver hydrocarbon precursors into the reaction chamber and the remote plasma source may generate hydrogen radicals for delivery into the reaction chamber.

At block 430 of the process 400, one or more hydrocarbon precursors are flowed into the reaction chamber and towards the substrate. Each of the one or more hydrocarbon precursors includes an alkene or alkyne group. This means that the hydrocarbon precursors include one or more unsaturated carbon bonds, such as one or more carbon-to-carbon double bonds and/or carbon-to-carbon triple bonds. Examples of hydrocarbon precursors having alkene or alkyne groups include but are not limited to toluene, benzene, ethylene, propylene, butene, pentadiene (e.g., 1,4 pentadiene), hexene, acetylene, propyne, butyne, or pentyne. In some implementations, each of the one or more hydrocarbon precursors may include a carbon chain having at least 2 carbon atoms, at least 3 carbon atoms, at least 4 carbon atoms, at least 5 carbon atoms, at least 6 carbon atoms, or at least 7 carbon atoms.

The one or more hydrocarbon precursors may flow into the reaction chamber through the one or more gas outlets fluidly coupled to the reaction chamber. The one or more gas outlets are positioned downstream from the remote plasma source. Plasma of the one or more hydrocarbon precursors is not generated in the reaction chamber or in the remote plasma source. Rather, the one or more hydrocarbon precursors are flowed into the reaction chamber independently of plasma generated in the remote plasma source.

The one or more hydrocarbon precursors are flowed towards the substrate to adsorb onto the metal surface or at least positioned in an environment adjacent to the metal surface of the substrate. In some implementations, the one or more hydrocarbon precursors are flowed into the reaction chamber simultaneous with plasma generation and plasma exposure as described at blocks 440 and 450. In some implementations, the one or more hydrocarbon precursors are flowed into the reaction chamber prior to plasma generation and plasma exposure as described at blocks 440 and 450.

In some implementations, the one or more hydrocarbon precursors are delivered with other species, notably carrier gas, into the environment adjacent to the metal surface of the substrate. Upstream from the deposition reaction surface, the one or more hydrocarbon precursors can be mixed with an inert carrier gas. Example inert carrier gases include, but are not limited to, argon (Ar) and helium (He). In some implementations, the one or more hydrocarbon precursors are delivered as a mixture of multiple hydrocarbon precursors. The multiple hydrocarbon precursors may be present in equimolar or relatively similar proportions as appropriate to form the primary backbone or matrix in the resulting graphene. In other embodiments, the relative amounts of the multiple hydrocarbon precursors are substantially skewed from equimolarity.

At block 440 of the process 400, radicals of hydrogen are generated, from a hydrogen source gas, in a remote plasma source that is positioned upstream of the one or more hydrocarbon precursors. Specifically, the radicals of hydrogen are generated in a remote plasma source that is upstream from the one or more gas outlets for introducing the one or more hydrocarbon precursors into the reaction chamber. The remote plasma source may be any suitable plasma source for plasma generation, such as an inductively-coupled plasma source or capacitively-coupled plasma source. In some implementations, the hydrogen source gas is hydrogen gas (H₂). In some implementations, the hydrogen gas is flowed into the remote plasma source together with one or more additional gases such as helium (He). In certain embodiments, hydrogen source gas is provided in a carrier gas such as helium. As an example, hydrogen gas may be provided in a helium carrier at a concentration of about 1-25% hydrogen or 1-10% hydrogen. Therefore, in some instances, H₂/He plasma is generated in the remote plasma source.

At block 450 of the process 400, the radicals of hydrogen are introduced into the reaction chamber and towards the substrate, where the radicals of hydrogen react with the one or more hydrocarbon precursors to deposit graphene on the metal surface of the substrate. The radicals of hydrogen are delivered into the reaction chamber under process conditions so that excited radicals transition to relaxed radicals without recombining. Pressure, fraction of carrier gas such as helium, geometry of gas ports of the showerhead, distance between the showerhead and the one or more gas outlets, and other process conditions are configured so that the hydrogen atoms encounter the substrate as radicals in a low energy state (e.g., ground state) without recombining. In some implementations, all or substantially all of the radicals of hydrogen in an environment adjacent to the substrate are radicals of hydrogen in the ground state. That way, the substrate is exposed to remote hydrogen plasma that minimizes surface growth damage.

Once generated, the radicals of hydrogen may be in an excited energy state. For example, hydrogen in an excited energy state can have an energy of at least 10.2 eV (first excited state). Excited radicals of hydrogen may cause surface growth damage of during graphene growth. In some implementations, when an excited hydrogen radical loses its energy, or relaxes, the excited hydrogen radical may become a substantially low energy state hydrogen radical or a ground state hydrogen radical. In some implementations, process conditions may be provided so that excited hydrogen radicals lose energy or relax to form substantially low energy state or ground state hydrogen radicals. For example, the remote plasma source or associated components may be designed so that a residence time of hydrogen radicals diffusing from the remote plasma source to the substrate is greater than the energetic relaxation time of an excited hydrogen radical. The energetic relaxation time for an excited hydrogen atom radical can be about equal to or less than about 1×10³ seconds.

An environment adjacent to the metal surface of the substrate may include the one or more hydrocarbon precursors. In addition, the environment adjacent to the metal surface of the substrate may include the radicals of hydrogen in the low energy state (e.g., ground state). The environment adjacent to the metal surface of the substrate comprises the metal surface as well as a space immediately above the exposed surface of the substrate. In effect, activation of the hydrocarbon precursors by radicals of hydrogen in the low energy state may occur on the metal surface or at a distance above the metal surface of the substrate. In some implementations, the distance above the metal surface of the substrate may be up to about 100 millimeters above the metal surface of the substrate. Typically, reaction conditions in the environment adjacent to the metal surface of the substrate are generally uniform across the entire metal surface of the substrate, though some variation may be permitted.

In some implementations, all, or substantially all, or a substantial fraction of the hydrogen atom radicals can be in the ground state, e.g., at least about 90% or 95% of the hydrogen atom radicals adjacent to the metal surface of the substrate are in the ground state. As used herein, radicals of hydrogen may also be referred to as “hydrogen radicals” and “hydrogen atom radicals.” A state in which a substantial fraction of hydrogen atom radicals are in the ground state can be achieved by various techniques. Some apparatuses, such as described in FIG. 2, are designed to achieve this state. The process conditions for achieving hydrogen atom radicals in the ground state may not have substantial amounts of ions, electrons, or radical species in high energy states such as states above the ground state. The presence of substantial amounts of ions or high energy radicals may cause surface growth damage on the substrate, resulting in low-quality graphene or disordered carbon growth. In some embodiments, the concentration of ions in the environment adjacent to the metal surface of the substrate is no greater than about 107/cm³. Hydrogen atom radicals in the ground state may provide sufficient energy for activating the one or more hydrocarbon precursors while providing mild conditions in the environment adjacent to the metal surface to limit surface growth damage.

The one or more hydrocarbon precursors are flowed into the reaction chamber downstream from the radicals of hydrogen. The radicals of hydrogen are generated in the remote plasma source located upstream from the one or more gas outlets for introducing the one or more hydrocarbon precursors. By the time the radicals of hydrogen reach the one or more hydrocarbon precursors, the radicals of hydrogen are in a low energy state or ground state upon mixing or interacting with the one or more hydrocarbon precursors.

Without being limited by any theory, one of the more kinetically favorable reaction mechanisms in the deposition reaction includes hydrogen abstraction, which results in an activated hydrocarbon precursors. Without being limited by any theory, the hydrogen radicals in the low energy state or ground state may interact with the alkyne or alkene groups in the hydrocarbon molecule that results in the formation of activated alkanes (e.g., methane). In some instances, the hydrocarbon precursor breaks down into smaller-chain hydrocarbon molecules or radicals. Activated alkanes contain at least one carbon radical as an active site, and the active sites can react together to form carbon-to-carbon bonds in graphene. Bonding at the active sites and cross-linking can form a primary backbone or matrix in a resulting graphene film. The metal surface may act as a catalyst to promote reactions between activated hydrocarbon precursors.

The hydrocarbon precursors do not serve as passive spectators, but significantly contribute to the composition of the graphene. In some implementations, substantially all or a substantial fraction of the atoms in graphene are provided by the one or more hydrocarbon precursors, with small amounts of hydrogen or other element from the remote hydrogen plasma providing less than about 5 atomic percent or less than about 2 atomic percent of the film mass. In such cases, the low energy hydrogen atom radicals used to drive the deposition reaction do not substantially contribute to the mass of the deposited graphene.

The temperature in the environment adjacent to the metal surface of the substrate can be any suitable temperature facilitating the deposition reaction. In some implementations, the temperature in the environment adjacent to the metal surface of the substrate can be largely controlled by the temperature of a pedestal on which a substrate is supported during deposition of graphene. In some implementations, the operating temperature can be equal to or less than about 500° C., equal to or less than about 450° C., equal to or less than about 400° C., equal to or less than about 350° C., equal to or less than about 300° C., between about 200° C. and about 400° C., or between about 200° C. and about 300° C. Such temperatures may be suitable for semiconductor applications. In some implementations, the temperature may depend on the metal of the metal surface on which the graphene is deposited. For example, copper may be able to sustain temperatures at 400° C. or below, whereas ruthenium may be able to sustain temperatures of 450° C. or below.

The pressure in the environment adjacent to the metal surface of the substrate can be any suitable pressure to promote graphene growth in the reaction chamber. In some embodiments, the pressure can be about 10 Torr or lower, or about 5 Torr or lower. For example, the pressure can be between about 1 Torr and about 2 Torr.

Graphene is selectively deposited on the metal surface from the reaction of radicals of hydrogen with the one or more hydrocarbon precursors provided downstream from the remote plasma source. Relatively mild reaction conditions provided by the radicals of hydrogen in a low energy state (e.g., ground state) activate the one or more hydrocarbon precursors to form carbon radicals. As such, the carbon radicals are formed outside of the remote plasma source in which plasma is generated. The amount of carbon radicals at the environment adjacent to the metal surface of the substrate may be controlled to limit having too many nucleation sites for graphene growth. Without being limited by any theory, an excess number of nucleation sites may correspond to an excess number of defects during graphene growth.

Graphene may be selectively deposited on a transition metal such as copper, ruthenium, nickel, molybdenum, cobalt, or combinations thereof. In some implementations, the metal surface includes copper. In some implementations, the graphene on the metal surface is relatively thin and may be on the order of a few monolayers thick. In some implementations, the thickness of the graphene is equal to or less than about 10 nm, equal to or less than about 5 nm, equal to or less than about 3 nm, or equal to or less than about 1 nm. The thickness of the graphene may depend on the metal surface on which it is deposited on. For example, the thickness of the graphene may be less than about 1 nm when deposited on copper. The graphene may be a single layer graphene, bilayer graphene, or few layer graphene. The Raman spectrum of the graphene may be characterized by a D peak that is negligible in intensity and having a 2D peak that is equal to or greater than a G peak. It will be understood that the intensity of the D peak will be significantly smaller than the 2D peak and the G peak.

In some implementations, the process 400 may further include annealing the graphene on the metal surface of the substrate. Annealing the graphene may occur at elevated temperatures to remove defects from the graphene crystal structure. This ensures formation of high-quality graphene. In some implementations, the elevated temperatures may be equal to or greater than about 200° C., equal to or greater than about 300° C., equal to or greater than about 400° C., or between about 200° C. and about 400° C. The elevated temperature for anneal may depend on the metal of the metal surface and the temperature limits compatible with back-end-of-line semiconductor processing. For example, the elevated temperature may be up to about 400° C. for copper. Annealing the graphene may result in significant improvement in the quality of graphene with reduced defects, where the D peak is decreased and the 2D peak is increased. In some implementations, annealing the graphene occurs in an inert gas atmosphere, where the inert gas atmosphere includes an inert gas such as argon (Ar), helium (He), nitrogen (N₂), or combinations thereof.

In the foregoing description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments are described in conjunction with the specific embodiments, it will be understood that it is not intended to limit the disclosed embodiments.

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

What is claimed is:

1. A method of depositing graphene on a metal surface of a substrate, the method comprising:
providing a substrate in a reaction chamber, wherein the substrate includes a metal surface;
flowing one or more hydrocarbon precursors into the reaction chamber and toward the substrate;
generating, from a hydrogen source gas, radicals of hydrogen in a remote plasma source that is positioned upstream of the one or more hydrocarbon precursors; and
introducing the radicals of hydrogen into the reaction chamber and toward the substrate, wherein the radicals of hydrogen react with the one or more hydrocarbon precursors to deposit graphene on the metal surface of the substrate.

2. The method of claim 1, wherein each of the one or more hydrocarbon precursors includes an alkene or alkyne group.

3. The method of claim 2, wherein each of the one or more hydrocarbon precursors includes toluene, benzene, ethylene, propylene, butene, pentene, pentadiene, hexene, acetylene, propyne, butyne, or pentyne.

4. The method of claim 1, wherein all or substantially all of the radicals of hydrogen in an environment adjacent to the substrate are radicals of hydrogen in a ground state.

5. The method of claim 1, wherein the substrate is maintained at a temperature between about 200° C. and about 400° C. during deposition of graphene on the metal surface of the substrate.

6. The method of claim 1, further comprising:
treating the metal surface of the substrate prior to depositing graphene on the metal surface, wherein treating the metal surface includes exposing the metal surface to a plasma of a reducing gas species.

7. The method of claim 6, wherein treating the metal surface further includes exposing the metal surface to a cyano-based radical species.

8. The method of claim 7, wherein treating the metal surface further includes generating, from at least a carbon-containing source gas and a nitrogen-containing source gas, a plasma containing the cyano-based radical species, wherein exposing the metal surface to the cyano-based radical species occurs before or after exposing the metal surface to the plasma of the reducing gas species.

9. The method of claim 7, wherein exposing the metal surface to the cyano-based radical species occurs simultaneous with exposing the metal surface to the plasma of the reducing gas species, wherein the cyano-based radical species is generated by exposing a downstream carbon-containing precursor having a cyano group to the plasma of the reducing gas species, wherein the plasma of the reducing gas species is generated in a remote plasma source that is positioned upstream of the downstream carbon-containing precursor.

10. The method of claim 7, wherein the plasma of the reducing gas species is a plasma of a reducing gas species and of a nitrogen-containing agent, wherein exposing the metal surface to the cyano-based radical species occurs simultaneous with exposing the metal surface to the plasma of the reducing gas species and of the nitrogen-containing agent, wherein the cyano-based radical species is generated by exposing a downstream carbon-containing precursor to the plasma of the reducing gas species, wherein the plasma of the reducing gas species and of the nitrogen-containing agent is generated in a remote plasma source that is positioned upstream of the downstream carbon-containing precursor.

11. The method of claim 1, wherein the metal surface includes copper, ruthenium, nickel, molybdenum, cobalt, or combinations thereof.

12. The method of claim 1, wherein the substrate is a semiconductor wafer or semiconducting workpiece, wherein the metal surface of the substrate faces towards the remote plasma source.

13. The method of claim 1, wherein the graphene is deposited under conditions that selectively deposit on a metal of the metal surface of the substrate without depositing on a dielectric material or other non-metal material.

14. The method of claim 1, further comprising:
annealing the graphene on the metal surface of the substrate at a temperature between about 200° C. and about 400° C.

15. An apparatus for depositing graphene on a metal surface of a substrate, the apparatus comprising:
a reaction chamber;
a substrate support in the reaction chamber and configured to support a substrate, wherein the substrate includes a metal surface;
a remote plasma source upstream of the reaction chamber, wherein the metal surface of the substrate faces towards the remote plasma source;
one or more gas outlets in the reaction chamber and downstream from the remote plasma source; and
a controller configured with instructions for performing the following operations:
flow one or more hydrocarbon precursors through the one or more gas outlets into the reaction chamber and toward the substrate;
generate, from a hydrogen source gas, radicals of hydrogen in the remote plasma source; and
introduce the radicals of hydrogen into the reaction chamber and towards the substrate, wherein the radicals of hydrogen react with the one or more hydrocarbon precursors to deposit graphene on the metal surface of the substrate.

16. A semiconducting device comprising:
a semiconductor substrate having a temperature sensitive underlayer, wherein the temperature sensitive underlayer has a temperature sensitive limit; and
a graphene film deposited on the temperature sensitive underlayer.

17. The semiconducting device of claim 16, wherein the temperature sensitive underlayer includes a transition metal, and wherein the temperature sensitive limit is between about 400° C. and about 700° C.

18. A method of depositing graphene on a metal surface of a substrate, the method comprising:
providing a substrate in a reaction chamber, wherein the substrate includes a metal surface; and
depositing graphene on the metal surface of the substrate, wherein the substrate is maintained at a temperature between about 200° C. and about 400° C. during deposition.

19. A method of depositing graphene on a metal surface of a substrate, the method comprising:
providing a substrate in a reaction chamber, wherein the substrate includes a metal surface;
treating the metal surface of the substrate prior to depositing graphene on the metal surface, wherein treating the metal surface includes exposing the metal surface to a plasma of a reducing gas species simultaneous with exposing the metal surface to a cyano-based radical species; and
depositing graphene on the metal surface of the substrate.

20. The method of claim 19, wherein the plasma of the reducing gas species is a plasma of a reducing gas species and of a nitrogen-containing agent, wherein the cyano-based radical species is generated by exposing a downstream carbon-containing precursor to the plasma of the reducing gas species and of the nitrogen-containing agent, wherein the plasma of the reducing gas species and of the nitrogen-containing agent is generated in a remote plasma source that is positioned upstream of the downstream carbon-containing precursor.
